(19) United States
(12) Patent Application Publication
(10) Pub. No.: US 2017/0051084 A1
(43) Pub. Date: Feb. 23, 2017

(54) FILTERING MATERIAL, FILTRATION FILTER, AND FILTRATION METHOD

(71) Applicant: TOKYO OHKA KOGYO CO., LTD., Kawasaki-shi (JP)

(72) Inventor: Isao HIRANO, Kawasaki-shi (JP)

(21) Appl. No.: 15/236,826

(22) Filed: Aug. 15, 2016

(30) Foreign Application Priority Data
Aug. 20, 2015 (JP) 2015-162673

(51) Int. Cl. C08F 8/32; B01J 20/26; B01D 39/04; G03F 7/32

(52) U.S. Cl. CPC C08F 8/32; G03F 7/322; B01J 20/265; B01D 39/04

(57) ABSTRACT

A filtering material which is used to filter a liquid chemical for lithography, in which a base material having a group represented by the following Formula (a0-1) is used:

(*-Ya⁰¹ₙW (a0-1)
in which Ya⁰¹ represents a divalent linking group; W represents a heteroatom-containing group, here, the group represented by W includes a nitrogen atom bonded to Ya⁰¹ and two or more heteroatoms other than the nitrogen atom bonded to Ya⁰¹; n represents a natural number; and * represents a valence bond with respect to the base material.

### RELATED APPLICATIONS

This application claims priority to Japanese Patent Application No. 2015-162673, filed Aug. 20, 2015, the entire content of which is incorporated herein by reference.

### BACKGROUND OF THE INVENTION

Field of the Invention

The present invention relates to a filtering material, a filtration filter, and a filtration method.

Description of Related Art

In recent years, processing of a further ultra-fine pattern has been required for manufacturing semiconductor substrates. Along with this, the analysis capability of a pattern defect inspection device is has improved, and accordingly, minute defects which have not been problems are assumed to be the cause of a reduction in yield at the time of a manufacturing process.

In ultra-pure purification of various liquid chemicals used for manufacturing an ultra-fine pattern, for example, it has been required to completely remove metal components formed of ionic compounds.

In the manufacture of an ultra-fine pattern, it is observed that lithograph characteristics are adversely affected by the presence of impurities that are considered to be metal ions with an extremely low concentration.

It is found that metal ion contamination of a resist composition is a cause of this problem. Further, it has been confirmed that the lithography characteristics are adversely affected just by the presence of less than 100 ppb (parts per billion) of metal ions in a resist composition.

In order to solve the above-described problems, attempts have been made to filter and purify the resist composition for removal of impurities such as metal ions.

For example, Patent Literatures 1 and 2 describe a method of filtering a resist composition using a filter sheet or the like that uses a functionalized silica gel.

Patent Literature 3 describes a method of removing impurities using an impurity filtration device that has polyolefin non-woven fabric with a specific fiber diameter and a specific density as a filtration member. Patent Literatures 4 to 6 describe a method of removing metals using a predetermined filtering medium. Patent Literature 7 describes a method of removing impurity metal components using an adsorbent.

### DOCUMENTS OF RELATED ART

### Patent Literature

[Patent Literature 1] Japanese Unexamined Patent Application, First Publication No. 2006-136883

[Patent Literature 2] Japanese Unexamined Patent Application, First Publication No. 2003-238958

[Patent Literature 3] Japanese Unexamined Patent Application, First Publication No. 2013-61426

[Patent Literature 4] Japanese Unexamined Patent Application, First Publication No. 2000-281739

[Patent Literature 5] Japanese Unexamined Patent Application, First Publication No. 2004-330056

[Patent Literature 6] Japanese Unexamined Patent Application, First Publication No. 2005-243728

[Patent Literature 7] Japanese Unexamined Patent Application, First Publication No. Hei 7-74073

### SUMMARY OF THE INVENTION

In manufacture of an ultra-fine pattern, it is required to completely remove metal components from various liquid chemicals for lithography used for all lithography processes. Particularly, it is required to completely remove metal components in an alkaline solution such as an alkali developer, a resist composition, or various resin compositions such as an insulating film forming resin composition and an antireflection film forming resin composition.

A cation exchange resin or the like is used for ultra-pure purification of a liquid chemical for lithography. However, since cation sites are occasionally eluted from the cation exchange resin, difficulty in ultra-pure purification or the like has been a problem. There is still room for improvement of a filtering material used for ultra-pure purification of a liquid chemical for lithography.

The present invention has been made in consideration of the above-described problems, and an object thereof is to provide a filtering material which is used to filter a liquid chemical for lithography and is capable of removing metal ion components in the liquid chemical for lithography; and a filtration filter and a filtration method using the filtering material.

According to a first aspect of the present invention, there is provided a filtering material which is used to filter a liquid chemical for lithography, the filtering material including a base material having a group represented by the following Formula (a0-1).

(*-Ya⁰¹ₙW (a0-1)

[In Formula (a0-1), Ya⁰¹ represents a divalent linking group; W represents a heteroatom-containing group, provided that the group represented by W includes a nitrogen atom bonded to Ya⁰¹ and two or more heteroatoms other than the nitrogen atom bonded to Ya⁰¹; n represents a natural number; and the symbol “*” represents a valence bond with respect to the base material.]

According to a second aspect of the present invention, there is provided a filtration filter which uses the filtering material according to the first aspect of the present invention.

According to a third aspect of the present invention, there is provided a filtration method including passing a liquid chemical for lithography through the filtration filter according to the second aspect of the present invention; and removing impurities in the liquid chemical for lithography.

According to the present invention, it is possible to provide a filtering material which is used to filter a liquid chemical for lithography and is capable of removing metal ion components in the liquid chemical for lithography; and a filtration filter and a filtration method using the filtering material.

### DETAILED DESCRIPTION OF THE INVENTION

In the present specification and the scopes of claims, the term “aliphatic” is a relative concept to the term “aromatic”, and defines a group or a compound that has no aromaticity.

The term “alkyl group” includes linear, branched or cyclic monovalent saturated hydrocarbon group, unless otherwise specified.

The term “alkylene group” includes linear, branched or cyclic divalent saturated hydrocarbon group, unless otherwise specified. The same applies to an alkyl group in an alkoxy group.

A “halogenated alkyl group” is a group in which some or all of the hydrogen atoms of an alkyl group is substituted with halogen atoms. Examples of the halogen atom include a fluorine atom, a chlorine atom, a bromine atom, and an iodine atom.

A “fluorinated alkyl group” or a “fluorinated alkylene group” is a group in which some or all of the hydrogen atoms of an alkyl group or an alkylene group have been substituted with fluorine atoms.

A “constituent unit” indicates a monomer unit constituting a polymer compound (a resin, a polymer, or a copolymer).

A “constituent unit derived from an acrylic acid ester” indicates a constituent unit formed by cleavage of an ethylenic double bond of an acrylic acid ester.

An “acrylic acid ester” indicates a compound in which a hydrogen atom of a carboxy group terminal of acrylic acid (CH₂═CH—COOH) is substituted with an organic group.

In an acrylic acid ester, a hydrogen atom bonded to a carbon atom at an α-position may be substituted with a substituent. The substituent (R^{α}) that is substituted with a hydrogen atom bonded to a carbon atom at the α-position is an atom or a group other than a hydrogen atom, and examples thereof include an alkyl group having 1 to 5 carbon atoms, a halogenated alkyl group having 1 to 5 carbon atoms, and a hydroxyalkyl group. Further, a carbon atom at the α-position of an acrylic acid ester indicates a carbon atom to which a carbonyl group is bonded unless otherwise specified.

Hereinafter, an acrylic acid ester in which a hydrogen atom bonded to a carbon atom at the α-position is substituted with a substituent is also referred to as an α-substituted acrylic acid ester. Further, the acrylic acid ester and the α-substituted acrylic acid ester are also collectively referred to as an “(α-substituted) acrylic acid ester”.

A “constituent unit derived from a hydroxystyrene derivative” indicates a constituent unit formed by cleavage of an ethylenic double bond of hydroxystyrene or a hydroxystyrene derivative.

The concept of a “hydroxystyrene derivative” includes derivatives obtained by a hydrogen atom at the α-position of hydroxystyrene being substituted with other substituents such as an alkyl group or a halogenated alkyl group; and derivatives thereof. Examples of the derivatives thereof include a derivative obtained by substituting a hydrogen atom of a hydroxyl group of hydroxystyrene, in which a hydrogen atom at the α-position may be substituted with a substituent, with an organic group; and a derivative obtained by a substituent other than a hydroxyl group being bonded to a benzene ring of hydroxystyrene in which a hydrogen atom at the α-position may be substituted with a substituent. In addition, the α-position (carbon atom at the α-position) indicates a carbon atom to which a benzene ring is bonded unless otherwise specified.

Examples of a substituent that is substituted with a hydrogen atom at the α-position of hydroxystyrene are the same as those exemplified as the substituents at the α-position in the α-substituted acrylic acid ester.

A “constituent unit derived from vinylbenzoic acid or a vinylbenzoic acid derivative” indicates a constituent unit formed by cleavage of an ethylenic double bond of vinylbenzoic acid or a vinylbenzoic acid derivative.

The concept of “a vinylbenzoic acid derivative” includes derivatives obtained by a hydrogen atom at the α-position of vinylbenzoic acid being substituted with other substituents such as an alkyl group or a halogenated alkyl group; and derivatives thereof. Examples of the derivatives thereof include a derivative obtained by substituting a hydrogen atom of a carboxy group of vinylbenzoic acid, in which a hydrogen atom at the α-position may be substituted with a substituent, with an organic group; and a derivative obtained by a substituent other than a hydroxyl group and a carboxy group being bonded to a benzene ring of vinylbenzoic acid in which a hydrogen atom at the α-position may be substituted with a substituent. In addition, the α-position (carbon atom at the α-position) indicates a carbon atom to which a benzene ring is bonded unless otherwise specified.

The concept of a “styrene derivative” includes derivatives obtained by a hydrogen atom at the α-position of styrene being substituted with other substituents such as an alkyl group or a halogenated alkyl group.

A “constituent unit derived from styrene” or a “constituent unit derived from a styrene derivative” indicates a constituent unit formed by cleavage of an ethylenic double bond of styrene or a styrene derivative.

As the alkyl group as a substituent at the α-position, a linear or branched alkyl group is preferable and specific examples thereof include an alkyl group having 1 to 5 carbon atoms (such as a methyl group, an ethyl group, a propyl group, an isopropyl group, an n-butyl group, an isobutyl group, a tert-butyl group, a pentyl group, an isopentyl group, or a neopentyl group).

Further, specific examples of the halogenated alkyl group as a substituent at the α-position include groups in which some or all of hydrogen atoms of the above-described “alkyl group as a substituent at the α-position” are substituted with halogen atoms. Examples of the halogen atom include a fluorine atom, a chlorine atom, a bromine atom, and an iodine atom. Among these, a fluorine atom is preferable.

In addition, specific examples of the hydroxyalkyl group as a substituent at the α-position include groups in which some or all of hydrogen atoms of the above-described “alkyl group as a substituent at the α-position” are substituted with a hydroxyl group. The number of hydroxyl groups in the hydroxyalkyl group is preferably in a range of 1 to 5 and most preferably 1.

The expression “may have a substituent” includes a case where a hydrogen atom (—H) is substituted with a monovalent group and a case where a methylene (—CH₂—) group is substituted with a divalent group.

The concept “exposure to light” indicates typical manners of irradiation with radiation.

An “organic group” indicates a group including carbon atoms, and the group may include atoms other than carbon atoms (such as hydrogen atoms, oxygen atoms, nitrogen atoms, sulfur atoms, and halogen atoms (fluorine atoms, chlorine atoms, and the like)).

Filtering Material

A filtering material according to the present embodiment can be used for applications of filling a filter cartridge or a column and being disposed in the inside of a filtration device.

For example, metal components in a liquid chemical for lithography can be removed in an excellent manner by passing the liquid chemical for lithography through a filter cartridge or a column, filled with the filtering material according to the present embodiment, for filtration.

Further, the filtering material according to the present embodiment may be added to a liquid chemical for lithography, stirred, and then mixed (for example, mixed by shaking the solution or causing rotational motion in a bottle). In this case, after the solution is stirred and mixed, the mixed solution of the filtering material and a liquid chemical for lithography may be filtered through a suitable filter.

The filtering material according to the present embodiment is used to filter a liquid chemical for lithography.

The liquid chemical for photolithography which is to be filtered is not particularly limited, and examples thereof include various liquid chemicals used to manufacture semiconductor elements or liquid crystal display elements.

The liquid chemical for photolithography contains a liquid chemical used to form a resist pattern, and examples thereof include an alkaline solution, a resist composition, an insulating film forming resin composition, an antireflection film forming resin composition, and a block copolymer composition used for a directed self assembly (DSA) technique.

As the filtering material according to the present embodiment, among those described above, an alkaline solution, a resist composition, an insulating film forming resin composition, or an antireflection film forming composition is preferable, an alkaline solution or an antireflection film forming composition is more preferable, and an alkaline solution is particularly preferable.

Alkaline Solution

Examples of the alkaline solution which can be filtered include alkaline solutions such as a tetramethylammonium hydroxide (TMAH) solution, a sodium hydroxide solution, and a potassium hydroxide solution. Among these, a tetramethylammonium hydroxide (TMAH) solution which is widely used as an alkali developer can be suitably filtered in a lithography technique.

Resist Composition

The resist composition is not particularly limited and various known resist compositions can be used as the resist composition.

Among known resist compositions, a resist composition including a base material component, an acid generator component, and an organic solvent component may be exemplified as the resist composition which can be suitably used for the resist pattern forming method of the present invention. It is preferable that the base material component has a constituent unit including an acid-decomposable group whose polarity is increased by an action of an acid. Examples of the acid generator component include various generators, for example, an onium salt-based acid generator such as an iodonium salt or a sulfonium salt. Preferred examples of the organic solvent component include propylene glycol monomethyl ether acetate (PGMEA) and propylene glycol monomethyl ether (PGME).

Insulating Film Forming Resin Composition

As the insulating film forming resin composition, a liquid containing a siloxane polymer, an organic hydride siloxane polymer, an organic hydride silsesquioxane polymer, a copolymer of hydrogen silsesquioxane and alkoxy hydride siloxane or hydroxy hydride siloxane, and an organic solvent component may be exemplified. In addition, as the insulating film forming resin composition, a composition containing a silsesquioxane resin, an acid generator component that generates an acid through exposure to light, a crosslinking component, and an organic solvent component may be exemplified.

Antireflection Film Forming Resin Composition

As the antireflection film forming resin composition, a liquid in which a plurality of epoxy moieties are present at the side chain of a core unit and which contains a polyfunctional epoxy compound to which one or more crosslinkable chromophores are bonded, a vinyl ether crosslinking agent, and an organic solvent component may be exemplified.

The “epoxy moiety” indicates at least one of a closed epoxide ring or a ring-opening (having reacted) epoxy group such as a reacted or unreacted glycidyl group or glycidyl ether group.

The “crosslinkable chromophore” indicates a light attenuation portion having a crosslinkable group in a free state (that is, unreacted) after a chromophore is bonded to a polyfunctional epoxy compound.

Examples of a monomer that guides a core unit include a monomer including a polyfunctional glycidyl such as tris(2,3-epoxypropyl)isocyanurate, tris(4-hydroxyphenyl)methane triglycidyl ether, trimethylopropane triglycidyl ether, poly(ethyleneglycol)diglycidyl ether, bis[4-(glycidyloxy)phenyl]methane, bisphenol A diglycidyl ether, 1,4-butanediol diglycidyl ether, resorcinol diglycidyl ether, 4-hydroxybenzoic acid diglycidyl ether, glycerol diglycidyl ether, 4,4′-methylenebis(N,N-diglycidylaniline), monoaryl diglycidyl isocyanurate, tetrakis(oxiranylmethyl)benzene,-1,2,4-5-tetracarboxylate, bis(2,3-epoxypropyl)terephthalate, or tris(oxiranylmethyl)benzene-1,2,4-tricarboxylate; 1,3-bis(2,4-bis(glycidyloxy)phenyl)adamantane, 1,3-bis(1-adamantyl)4,6-bis(glycidyloxy)benzene, 1-(2′,4′-bis(glycidyloxy)phenyl)adamantane, or 1,3-bis(4′-glycidyloxyphenyl)adamantane; and a polymer such as [(phenylglycidylether)-co-formaldehyde], poly[(o-cresylglycidylether)-co-formaldehyde], poly(glycidylmethacrylate), poly(bisphenol A-co-epichlorohydrin)-glycidyl end cap, poly(styrene-co-glycidylmethacrylate), or poly(tert-butylmethacrylate-co-glycidylmethacrylate).

Examples of a precursor (compound before bonding) of the chromophore include 1-hydroxy-2-naphthoic acid, 2-hydroxy-1-naphthoic acid, 6-hydroxy-2-naphthoic acid, 3-hydroxy-2-naphthoic acid, 1,4-dihydroxy-2-naphthoic acid, 3,5-dihydroxy-2-naphthoic acid, 3,7-dihydroxy-2-naphthoic acid, 1,1′-methylene-bis(2-hydroxy-3-naphthoic acid), 2,3-dihydroxybenzoic acid, 2,4-dihydroxybenzoic acid, 2,6-dihydroxybenzoic acid, 3,4-dihydroxybenzoic acid, 3,5-dihydroxybenzoic acid, 3,5-dihydroxy-4-methylbenzoic acid, 3-hydroxy-2-anthracenecarboxylic acid, 1-hydroxy-2-anthracenecarboxylic acid, 3-hydroxy-4-methoxymandelic acid, gallic acid, and 4-hydroxybenzoic acid.

Block Copolymer Composition

As the block copolymer composition used for the DSA technique, a liquid containing a block copolymer and an organic solvent component may be exemplified.

A polymer compound formed by bonding a hydrophobic polymer block (b11) and a hydrophilic polymer block (b21) to each other can be suitably used as the block copolymer.

The hydrophobic polymer block (b11) (hereinafter, also referred to as the “block (b11)”) is a block formed of a polymer (hydrophobic polymer) obtained by polymerization of monomers having a relatively low affinity for water from among a plurality of monomers having affinities for water which are relatively different from each other. The hydrophilic polymer block (b21) (hereinafter, also referred to as the “block (b21)”) is a block formed of a polymer (hydrophilic polymer) obtained by polymerization of monomers having a relatively high affinity for water from among the above-described plurality of monomers.

The block (b11) and the block (b21) are not particularly limited as long as phase separation occurs in the combinations thereof, but a combination of blocks which are incompatible with each other is preferable.

Further, it is preferable that the block (b11) and the block (b21) are combinations in which a phase formed of at least one kind of block in plural kinds of blocks constituting a block copolymer can be easily removed relative to other phases formed of plural blocks.

The kinds of blocks constituting a block copolymer may be two or three or more.

Moreover, in the block copolymer, partial constituent components (blocks) other than the block (b11) and the block (b21) may be bonded.

Examples of the block (b11) and the block (b21) include a block to which constituent units derived from styrene or a styrene derivative are repeatedly bonded; a block to which constituent units (constituent units derived from the (α-substituted) acrylic acid ester), derived from an acrylic acid ester in which a hydrogen atom bonded to a carbon atom at the α-position may be substituted with a substituent, are repeatedly bonded; a block to which constituent units (constituent units derived from the (α-substituted) acrylic acid), derived from acrylic acid in which a hydrogen atom bonded to a carbon atom at the α-position may be substituted with a substituent, are repeatedly bonded; a block to which constituent units derived from siloxane or a derivative thereof are repeatedly bonded; a block to which constituent units derived from alkylene oxide are repeatedly bonded; and a block to which silsesquioxane structure-containing constituent units are repeatedly bonded.

Examples of the styrene derivative include those in which a hydrogen atom at the α-position of styrene is substituted with a substituent such as an alkyl group or a halogenated alkyl group; and derivatives thereof. Examples of the derivatives thereof include those formed by a substituent being bonded to a benzene ring of styrene in which a hydrogen atom at the α-position may be substituted with a substituent. Examples of the substituent include an alkyl group having 1 to 5 carbon atoms, a halogenated alkyl group having 1 to 5 carbon atoms, and a hydroxyalkyl group.

Specific examples of the styrene derivative include α-methylstyrene, 2-methylstyrene, 3-methylstyrene, 4-methylstyrene, 4-t-butylstyrene, 4-n-octylstyrene, 2,4,6-trimethylstyrene, 4-methoxystyrene, 4-t-butoxystyrene, 4-hydroxystyrene, 4-nitrostyrene, 3-nitrostyrene, 4-chlorostyrene, 4-fluorostyrene, 4-acetoxy vinyl styrene, and 4-vinyl benzyl chloride.

Examples of the (α-substituted) acrylic acid ester include an acrylic acid ester and an acrylic acid ester in which a hydrogen atom bonded to a carbon atom at the α-position is substituted with a substituent. Examples of the substituent include an alkyl group having 1 to 5 carbon atoms, a halogenated alkyl group having 1 to 5 carbon atoms, and a hydroxyalkyl group.

Specific examples of the (α-substituted) acrylic acid ester include an acrylic acid ester such as methyl acrylate, ethyl acrylate, propyl acrylate, n-butyl acrylate, t-butyl acrylate, cyclohexyl acrylate, octyl acrylate, nonyl acrylate, hydroxyethyl acrylate, hydroxypropyl acrylate, benzyl acrylate, anthracene acrylate, glycidyl acrylate, 3,4-epoxycyclohexylmethane acrylate, or propyl trimethoxysilane acrylate; and a methacrylic acid ester such as methyl methacrylate, ethyl methacrylate, propyl methacrylate, n-butyl methacrylate, t-butyl methacrylate, cyclohexyl methacrylate, octyl methacrylate, nonyl methacrylate, hydroxyethyl methacrylate, hydroxypropyl methacrylate, benzyl methacrylate, anthracene methacrylate, glycidyl methacrylate, 3,4-epoxycyclohexylmethane methacrylate, or propyl trimethoxysilane methacrylate.

Examples of the (α-substituted) acrylic acid include acrylic acid and acrylic acid in which a hydrogen atom bonded to a carbon atom at the α-position is substituted with a substituent. Examples of the substituent include an alkyl group having 1 to 5 carbon atoms, a halogenated alkyl group having 1 to 5 carbon atoms, and a hydroxyalkyl group. Specific examples of the (α-substituted) acrylic acid include acrylic acid and methacrylic acid.

Examples of siloxane and a derivative thereof include dimethylsiloxane, diethylsiloxane, diphenylsiloxane, and methylphenylsiloxane.

Examples of alkylene oxide include ethylene oxide, propylene oxide, isopropylene oxide, and butylene oxide.

As the silsesquioxane structure-containing constituent unit, a cage type silsesquioxane structure-containing constituent unit is preferable. As a monomer that provides the cage type silsesquioxane structure-containing constituent unit, a compound including a cage type silsesquioxane structure and a polymerizable group may be exemplified.

Examples of such a block copolymer include a polymer compound formed by bonding a block to which constituent units derived from styrene or a styrene derivative are repeatedly bonded to a block to which constituent units derived from an (α-substituted) acrylic acid ester are repeatedly bonded; a polymer compound formed by bonding a block to which constituent units derived from styrene or a styrene derivative are repeatedly bonded to a block to which constituent units derived from (α-substituted) acrylic acid are repeatedly bonded; a polymer compound formed by bonding a block to which constituent units derived from styrene or a styrene derivative are repeatedly bonded to a block to which constituent units derived from siloxane or a derivative thereof are repeatedly bonded; a polymer compound formed by bonding a block to which constituent units derived from alkylene oxide are repeatedly bonded to a block to which constituent units derived from an (α-substituted) acrylic acid ester are repeatedly bonded; a polymer compound formed by bonding a block to which constituent units derived from alkylene oxide are repeatedly bonded to a block to which constituent units derived from (α-substituted) acrylic acid are repeatedly bonded; a polymer compound formed by bonding a block to which cage type silsesquioxane structure-containing constituent units are repeatedly bonded to a block to which constituent units derived from an (α-substituted) acrylic acid ester are repeatedly bonded; a polymer compound formed by bonding a block to which cage type silsesquioxane structure-containing constituent units are repeatedly bonded to a block to which constituent units derived from (α-substituted) acrylic acid are repeatedly bonded; and a polymer compound formed by bonding a block to which cage type silsesquioxane structure-containing constituent units are repeatedly bonded to a block to which constituent units derived from siloxane or a derivative thereof are repeatedly bonded.

Specific examples of such a block copolymer include a polystyrene-polymethylmethacrylate (PS-PMMA) block copolymer, a polystyrene-polyethylmethacrylate block copolymer, a polystyrene-(poly-t-butylmethacrylate) block copolymer, a polystyrene-polymethacrylate block copolymer, a polystyrene-polymethylacrylate block copolymer, a polystyrene-polyethylacrylate block copolymer, a polystyrene-(poly-t-butylacrylate) block copolymer, and a polystyrene-polyacrylate block copolymer.

### First Embodiment

A first embodiment of a filtering material of the present invention will be described.

The filtering material according to the first embodiment of the present invention is a material in which a base material is modified with a group represented by Formula (a0-1).

(*-Ya⁰¹ₙW (a0-1)

[In Formula (a0-1), Ya⁰¹ represents a divalent linking group. W represents a heteroatom-containing group. Here, the group represented by W includes a nitrogen atom bonded to Ya⁰¹ and two or more heteroatoms other than the nitrogen atom bonded to Ya⁰¹. n represents a natural number. The symbol “*” represents a valence bond with respect to the base material.]

Ya⁰¹

In Formula (a0-1), Ya01 represents a divalent linking group.

The divalent linking group as Ya⁰¹ is not particularly limited, and preferred examples thereof include a divalent hydrocarbon group which may have a substituent and a divalent linking group having heteroatoms.

Divalent hydrocarbon group which may have substituent

The hydrocarbon group as a divalent linking group may be an aliphatic hydrocarbon group or an aromatic hydrocarbon group.

Aliphatic Hydrocarbon Group

The aliphatic hydrocarbon group indicates a hydrocarbon group which does not have aromaticity.

Examples of the aliphatic hydrocarbon group as a divalent hydrocarbon group in Ya⁰¹ include a linear or branched group and a group having a ring in the structure.

The aliphatic hydrocarbon group may be saturated or unsaturated, but is preferably saturated.

As Ya⁰¹, the above-described divalent hydrocarbon groups bonded to each other through an ether bond, a urethane bond, a sulfide bond, or an amide bond may be exemplified.

The number of carbon atoms of the linear or branched aliphatic hydrocarbon group is preferably in a range of 1 to 10, more preferably in a range of 1 to 6, still more preferably in a range of 1 to 4, and most preferably in a range of 1 to 3.

As the linear aliphatic hydrocarbon group, a linear alkylene group is preferable, and specific examples thereof include a methylene group [—CH₂—], an ethylene group a trimethylene group [—(CH₂)₃—], a tetramethylene group [—(CH₂)₄-] and a pentamethylene group [—(CH₂)₅—]. Among these, a methylene group [—CH₂—], an ethylene group [—(CH₂)₂—], or a trimethylene group [—(CH₂)₃-] is preferable.

As the branched aliphatic hydrocarbon group, a branched alkylene group is preferable, and specific examples thereof include alkylalkylene groups, for example, an alkylmethylene group such as —CH(CH₃)—, —CH(CH₂CH₃)—, —C(CH₃)₂—, —C(CH₃)(CH₂CH₃)—, —C(CH₃)(CH₂CH₂CH₃)—, or —C(CH₂CH₃)₂—; an alkylethylene group such as —CH(CH₃)CH₂—, —CH(CH₃)CH(CH₃)—, —C(CH₃)₂CH₂—, —CH(CH₂CH₃)CH₂—, or —C(CH₂CH₃)₂—CH₂—; an alkyltrimethylene group such as —CH(CH₃)CH₂CH₂— or —CH₂CH(CH₃)CH₂—; and an alkyltetramethylene group such as —CH(CH₃)CH₂CH₂CH₂— or —CH₂CH(CH₃)CH₂CH₂—. As an alkyl group in the alkylalkylene group, a linear alkyl group of 1 to 5 carbon atoms is preferable.

Examples of the aliphatic hydrocarbon group having a ring in the structure include an alicyclic hydrocarbon group (group formed by removing two hydrogen atoms from an aliphatic hydrocarbon ring); a group in which an alicyclic hydrocarbon group is bonded to the terminal of a linear or branched aliphatic hydrocarbon group; and a group in which ah alicyclic hydrocarbon group is interposed in the middle of a linear or branched aliphatic hydrocarbon group. Examples of the linear and the branched aliphatic hydrocarbon group are the same as those described above.

The number of carbon atoms of the alicyclic hydrocarbon group is preferably in a range of 3 to 20 and more preferably in a range of 3 to 12.

The alicyclic hydrocarbon group may be monocyclic or polycyclic. As the monocyclic alicyclic hydrocarbon group, a group formed by removing two hydrogen atoms from monocycloalkane is preferable. The number of carbon atoms of the monocycloalkane is preferably in a range of 3 to 6, and specific examples thereof include cyclopentane and cyclohexane. As the polycyclic alicyclic hydrocarbon group, a group formed by removing two hydrogen atoms from polycycloalkane is preferable. The number of carbon atoms of the polycycloalkane is preferably in a range of 7 to 12, and specific examples thereof include adamantane, norbomane, isobomane, tricyclodecane and tetracyclododecane.

The linear or branched aliphatic hydrocarbon group may or may not have a substituent. Examples of the substituent include an alkyl group, an alkoxy group, a halogen atom, a halogenated alkyl group, a hydroxyl group, and a carbonyl group.

Examples of the alkyl group as a substituent include an alkyl group having 1 to 5 carbon atoms, and more specific examples thereof include a methyl group, an ethyl group, a propyl group, an n-butyl group, a tert-butyl group.

Examples of the alkoxy group as a substituent include an alkoxy group having 1 to 5 carbon atoms, and specific examples thereof include a methoxy group, an ethoxy group, an n-propoxy group, an iso-propoxy group, an n-butoxy group, and a tert-butoxy group. Among these, a methoxy group or an ethoxy group is preferable.

Examples of the halogen atom as a substituent include a fluorine atom, a chlorine atom, a bromine atom, and an iodine atom.

As the halogenated alkyl group as a substituent, a group in which some or all hydrogen atoms of the alkyl group are substituted with the halogen atoms may be exemplified.

In a cyclic aliphatic hydrocarbon group, some carbon atoms constituting the ring structure may be substituted with a substituent having heteroatoms. Examples of the substituent having heteroatoms include —O—, —C(═O)—O—, —S—, —S(═O)₂—, and —S(═O)₂—O—.

Examples of the aliphatic hydrocarbon group having a ring in the structure include a cyclic aliphatic hydrocarbon group (group formed by removing two hydrogen atoms from an aliphatic hydrocarbon ring) which may include a substituent having heteroatoms in a ring structure; a group in which a cyclic aliphatic hydrocarbon group is bonded to the terminal of a linear or branched aliphatic hydrocarbon group; and a group in which a cyclic aliphatic hydrocarbon group is interposed in the middle of a linear or branched aliphatic hydrocarbon group. Examples of the linear and the branched aliphatic hydrocarbon group are the same as those described above.

The number of carbon atoms of the cyclic aliphatic hydrocarbon group is preferably in a range of 3 to 20 and more preferably in a range of 3 to 12.

Specific examples of the cyclic aliphatic hydrocarbon group are the same as those described above.

The cyclic aliphatic hydrocarbon group may or may not include a substituent. Examples of the substituents are the same as those described above.

Aromatic Hydrocarbon Group

An aromatic hydrocarbon group is a hydrocarbon group having an aromatic ring.

The number of carbon atoms of the aromatic hydrocarbon group as a divalent hydrocarbon group in Ya⁰¹ is preferably in a range of 3 to 30, more preferably in a range of 5 to 30, still more preferably in a range of 5 to 20, particularly preferably in a range of 6 to 15, and most preferably in a range of 6 to 10. In this case, the number of carbon atoms does not include carbon atoms of a substituent.

Specific examples of the aromatic ring included in the aromatic hydrocarbon group include an aromatic hydrocarbon ring such as benzene, biphenyl, fluorene, naphthalene, anthracene or phenanthrene; and an aromatic heterocycle in which some carbon atoms constituting the aromatic hydrocarbon ring are substituted with heteroatoms. Examples of the heteroatom in an aromatic heterocycle include an oxygen atom, a sulfur atom and a nitrogen atom.

Specific examples of the aromatic hydrocarbon group include a group (arylene group) formed by removing two hydrogen atoms from the aromatic hydrocarbon ring; and a group in which one hydrogen atom of a group (aryl group) formed by removing one hydrogen atom from the aromatic hydrocarbon ring is substituted with an alkylene group (for example, a group formed by removing one more hydrogen atom from an aryl group in an arylalkyl group such as a benzyl group, a phenethyl group, a 1-naphthylmethyl group, a 2-naphthylmethyl group, a 1-naphthylethyl group, or a 2-naphthylethyl group). The number of carbon atoms of the alkylene group (alkyl chain in the arylalkyl group) is preferably in a range of 1 to 4, more preferably 1 or 2, and particularly preferably 1.

Specific examples of the aromatic hydrocarbon group as a divalent hydrocarbon group are the same as those described above.

In the aromatic hydrocarbon group, a hydrogen atom included in the aromatic hydrocarbon group may be substituted with a substituent. For example, a hydrogen atom bonded to an aromatic ring in the aromatic hydrocarbon group may be substituted with a substituent. Examples of the substituent include an alkyl group, an alkoxy group, a halogen atom, a halogenated alkyl group, and a hydroxyl group.

As the alkyl group serving as a substituent, an alkyl group having 1 to 5 carbon atoms is preferable and a methyl group, an ethyl group, a propyl group, an n-butyl group, or a tert-butyl group is most preferable.

Examples of the alkoxy group, the halogen atom, and the halogenated alkyl group serving as a substituent include those exemplified as substituents that are substituted with hydrogen atoms included in the cyclic aliphatic hydrocarbon group.

Divalent Linking Group Having Heteroatoms

A heteroatom in a divalent linking group including heteroatoms is an atom other than a carbon atom and a hydrogen atom, and examples thereof include an oxygen atom, a nitrogen atom, a sulfur atom, and a halogen atom.

In a case where Ya⁰¹ represents a divalent linking group having heteroatoms, preferable examples of the linking group include —O—, —C(═O)—O—, —C(═O)—, —O—C(═O)—O—, —C(═O)—NH—, —NH—, —NH—C(═NH)— (here, H may be substituted with a substituent such as an alkyl group or an acyl group), —S—, —S(═O)₂—, —S(═O)₂—O—, a group represented by Formula —Y²¹—O—Y²²—, —Y²¹—O—, —Y²¹—C(═O)—O—, —C(═O)—O—Y²¹—, [Y²¹—C(O)—O]_{m′}—Y²²—, or —Y²¹—O—C(═O)—Y²²— [in the formulae, Y²¹ and Y²² each independently represents a divalent hydrocarbon group which may have a substituent; O represents an oxygen atom; and m′ represents an integer of 0 to 3].

In a case where the divalent linking group having heteroatoms represents —C(═O)—NH—, —NH—, or —NH—C(═NH)—, H may be substituted with a substituent such as an alkyl group or an acyl group. The number of carbon atoms of the substituent (an alkyl group or an acyl group) is preferably in a range of 1 to 10, more preferably in a range of 1 to 8, and particularly preferably in a range of 1 to 5.

In Formula —Y²¹—O—Y²²—, —Y²¹—C(═O)—O—, —C(═O)—O—Y²¹, —[Y²¹—C(═O)—O]_{m′}—Y²²—, or —Y²¹—O—C(═O)—Y²²—, Y²¹ and Y²² each independently represent a divalent hydrocarbon group which may have a substituent. The divalent hydrocarbon groups are the same as those as the “divalent hydrocarbon groups which may have a substituent” described as a divalent linking group.

As Y²¹, a linear aliphatic hydrocarbon group is preferable, a linear alkylene group is more preferable, a linear alkylene group having 1 to 5 carbon atoms is still more preferable, and a methylene group or an ethylene group is particularly preferable.

As Y²², a linear or branched aliphatic hydrocarbon group is preferable, and a methylene group, an ethylene group, or an alkylmethylene group is more preferable. As an alkyl group in the alkylmethylene group, a linear alkyl group having 1 to 5 carbon atoms is preferable, a linear alkyl group having 1 to 3 carbon atoms is more preferable, and a methyl group is most preferable.

In the group represented by Formula —[Y²¹—C(═O)—O]_{m′}—Y²²—, m′ represents an integer of 0 to 3, preferably an integer of 0 to 2, more preferably 0 or 1, and particularly preferably 1. That is, a group represented by Formula —Y²¹—C(═O)—O—Y²²— is particularly preferable as the group represented by Formula —[Y²¹—C(═O)—O]_{m′}—Y²²—. Among these, a group represented by Formula —(CH₂)_{a′}—C(═O)—O—(CH₂)_{b′}— is preferable. In Formula, a′ represents an integer of 1 to 10, preferably an integer of 1 to 8, more preferably an integer of 1 to 5, still more preferably 1 or 2, and most preferably 1. b′ represents an integer of 1 to 10, preferably an integer of 1 to 8, more preferably an integer of 1 to 5, still more preferably 1 or 2, and most preferably 1.

In the first embodiment, from the viewpoint of synthesis, it is preferable that a divalent linking group as Ya⁰¹ has a hydroxyl group as a substituent.

In the present invention, as Ya⁰¹, a linear or branched alkylene group having a hydroxyl group as a substituent is preferable and a methylene group [—CH₂—], an ethylene group [—(CH₂)₂—], or a trimethylene group [—(CH₂)₃—] having a hydroxyl group as a substituent is more preferable.

W

In Formula (a0-1), W represents a heteroatom-containing group. The heteroatom-containing group as W functions as a site (hereinafter, also noted as a “chelate site”) that captures metal components in a liquid chemical for lithography.

In the present specification, the “metal components” indicate various metal components such as lithium, sodium, magnesium, potassium, chromium, manganese, iron, cobalt, nickel, copper, zinc, strontium, molybdenum, silver, cadmium, tin, antimony, barium, and lead. Particularly, the “metal components” indicate metal ions having a high ionization tendency, for example, an alkali metal ion such as a potassium ion or a sodium ion and an alkaline-earth metal ion such as calcium; and heavy metal ions such as an iron ion and a nickel ion.

According to the filtering material of the first embodiment of the present invention, the above-described metal components can be removed.

The heteroatom-containing group as W is a group which contains two or more heteroatoms functioning as a ligand, which coordinates with a metal component, and has an ability (hereinafter, also noted as “chelating ability”) to capture metal components in a liquid chemical for lithography.

The heteroatom included in W is not particularly limited as long as the heteroatom is capable of capturing the above-described metal components, and preferred examples of the heteroatom include an oxygen atom, a nitrogen atom, a sulfur atom, and a phosphorus atom. Among these, an oxygen atom or a nitrogen atom is more preferable.

A group represented by W is bonded to Ya⁰¹ through a nitrogen atom and includes two or more heteroatoms other than a nitrogen atom bonded to Ya⁰¹.

As a heteroatom-containing group represented by W, a hydrocarbon group including two or more heteroatoms may be exemplified. The hydrocarbon group may be an aliphatic hydrocarbon group or an aromatic hydrocarbon group, and preferred examples thereof include a chain aliphatic hydrocarbon group including two or more heteroatoms and a cyclic aliphatic hydrocarbon group including two or more heteroatoms.

In a case where W represents a chain aliphatic hydrocarbon group including heteroatoms, the number of carbon atoms of the hydrocarbon group is not particularly limited and can be suitably set according to metal components to be captured.

In the case where W represents a chain aliphatic hydrocarbon group including heteroatoms, since the chain aliphatic hydrocarbon group is unlikely to be affected by the size of a metal ion of a metal component to be captured, various metal components can be suitably removed.

In a case where W represents a cyclic aliphatic hydrocarbon group including heteroatoms, the number of carbon atoms constituting a ring can be suitably set according to metal components to be captured.

Specific examples of the heteroatom-containing group as W will be described later.

It is preferable that W in Formula (a0-1) according to the first embodiment represents a heteroatom-containing group having two or more ether bonds or two or more groups represented by —NH—.

Hereinafter, a filtering material that includes a heteroatom-containing group having two or more ether bonds is also noted as a “polyether group-modified filtering material” and a filtering material that includes a heteroatom-containing group having two or more groups represented by —NH— is also noted as a “polyamine group-modified filtering material”.

In a case of the polyether group-modified filtering material, metal ions having a high ionization tendency, for example, an alkali metal ion such as a potassium ion or a sodium ion and an alkaline-earth metal ion such as calcium can be suitably captured.

Further, in a case of the polyamine group-modified filtering material, heavy metals such as iron and nickel can be suitably captured.

In Formula (a0-1), n represents a natural number, preferably a natural number of 1 to 5, more preferably a natural number of 1 to 3, and particularly preferably 1 or 2.

Polyether Group-Modified Filtering Material

In a case of the polyether group-modified filtering material, it is preferable that W in Formula (a0-1) represents a cyclic polyether group represented by the following Formula (a0-r-1).

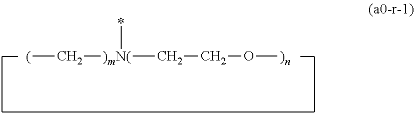

[In Formula (a0-r-1), n represents a natural number; m represents 0 or a natural number; and the symbol “*” represents a valence bond with respect to Ya⁰¹.]

Specific examples of the cyclic polyether group represented by Formula (a0-r-1) include groups formed by removing one hydrogen atom on a nitrogen atom such as 1-aza-12-crown-4, 1-aza-13-crown-4, 1-aza-14-crown-4, 1-aza-15-crown-5, 1-aza-16-crown-5, 1-aza-17-crown-5, 1-aza-18-crown-6, 1-aza-20-crown-6, 1-aza-21-crown-7, or 1-aza-24-crown-8.

Polyamine Group-Modified Filtering Material

In a case of the polyamine group-modified filtering material, it is preferable that W in Formula (a0-1) represents a chain or cyclic polyamine group represented by the following Formula (a0-r-2).

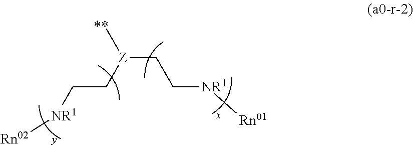

[In Formula (a0-r-2), Z represents a nitrogen atom. The symbol “**” represents a valence bond with respect to Ya⁰¹. R¹'s each independently represent a hydrogen atom or a methyl group. R¹ may be bonded to a divalent linking group as Ya⁰¹, other than Ya⁰¹ to which a nitrogen atom represented by Z is bonded. Rn⁰¹ and Rn⁰² each independently represent a hydrogen atom or a methyl group. Rn⁰¹ and Rn⁰² may be bonded to each other and form a ring. x and y each independently represent 0 or a natural number of 1 or greater. Here, the group represented by W has two or more groups represented by —NH— unless both of x and y represent 0.]

In Formula (a0-r-2), R¹, Rn⁰¹, and Rn⁰² each independently represent a hydrogen atom or a methyl group. In a case where a group represented by Formula (a0-r-2) is a chain polyamine group, groups represented by the following Formulae (a0-r-2-1) to (a0-r-2-6) are preferable.

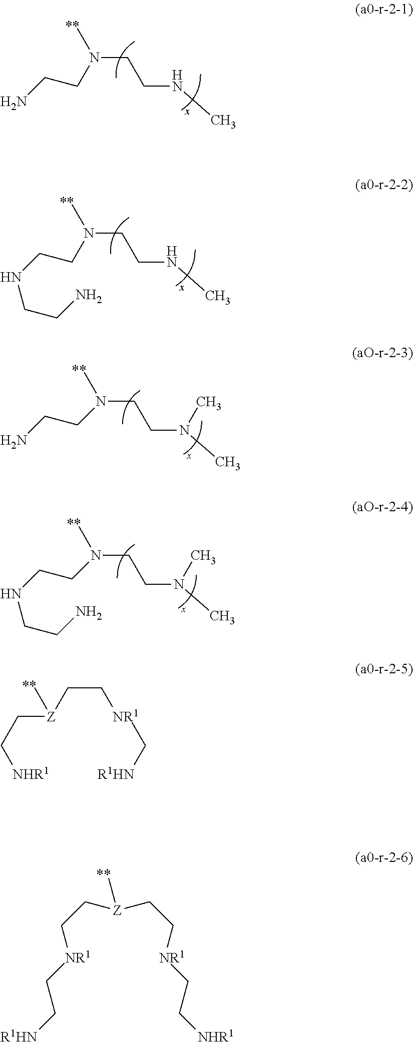

[In Formulae (a0-r-2-]) to (a0-r-2-4), X represents a natural number. The symbol “**” represents a valence bond with respect to Ya⁰¹⁻.

In Formulae (a0-r-2-5) and (a0-r-2-6), Z represents a nitrogen atom. The symbol “**” represents a valence bond with respect to Ya⁰¹. R¹'s each independently represent a hydrogen atom or a methyl group. R¹ may be bonded to Ya⁰¹ which is a divalent linking group other than Ya⁰¹ to which a nitrogen atom represented by Z is bonded.

In Formula (a0-r-2), in a case where Rn⁰¹ and Rn⁰² are bonded to each other and form a ring, a group represented by any of the following Formula (a0-rc-2-1) to (a0-rc-2-12) is preferable as the heteroatom-containing group represented by W. In the following Formula (a0-rc-2-1) to (a0-rc-2-12), Z represents a nitrogen atom and the symbol “**” represents a valence bond with respect to Ya⁰¹. R¹'s each independently represent a hydrogen atom or a methyl group. Further, R¹ may be bonded to Ya⁰¹ which is a divalent linking group other than Ya⁰¹ to which a nitrogen atom represented by Z is bonded.

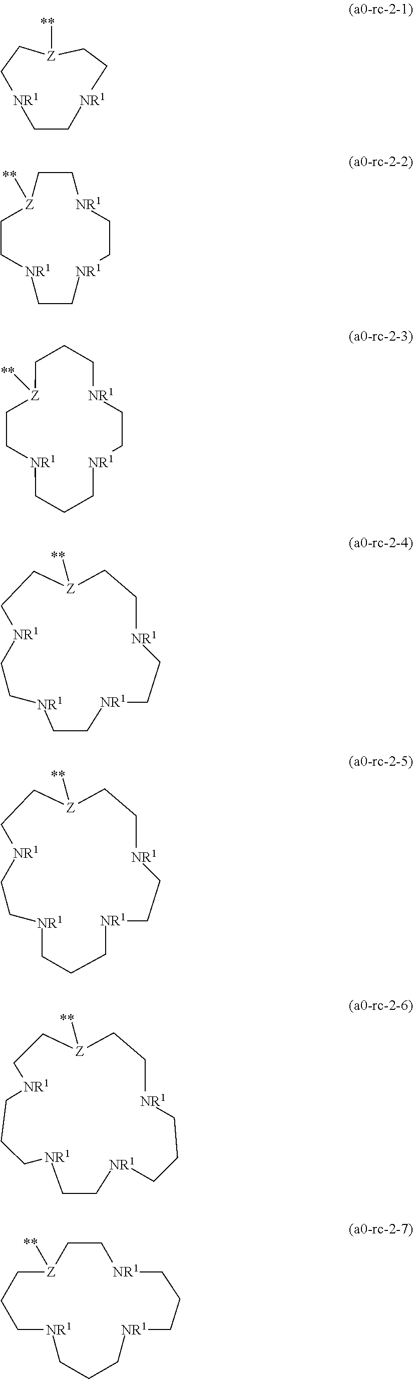

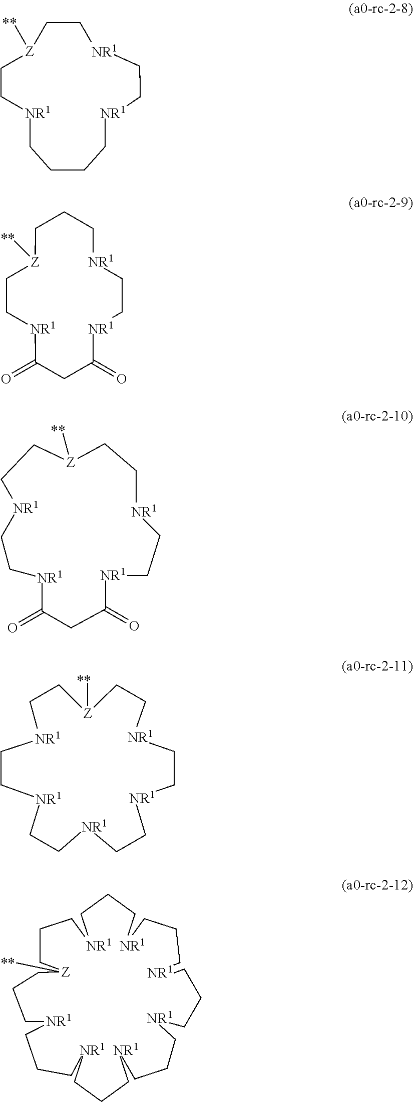

In the filtering material according to the first embodiment of the present invention, a base material modified with a group represented by Formula (a0-1) will be described.

Examples of the base material used for the filtering material according to the first embodiment include known porous base materials and a polymer compound that has a constituent unit having a group represented by Formula (a0-1).

Specifically, filters using resin materials are preferable as known porous base materials.

Examples of such filters include filters which use a thermoplastic resin, such as polyethylene, polypropylene, polyolefin which includes the same polyolefin, such as a homopolymer of polyolefin, a copolymer of polyolefin, or a terpolymer of polyolefin, polyvinylidene fluoride (PVDF), a PTFE resin, PFA, and other fluoride resins, a perfluorinated thermoplastic resin, a homopolymer and a copolymer of polyvinyl chloride (PVC), plastic, for example, a cellulose derivative material such as regenerated cellulose or nitrocellulose, nylon, polyamide, polysulfone, modified polysulfone such as polyether sulfone, polyaryl sulfone, or polyphenyl sulfone, polyimide, polycarbonate, PET and polyester similar to PET, and a mixture of these.

Among these, filters using polyethylene (PE), polypropylene (PP), polytetrafluoroethylene (PTFE), polyester, cellulose, polyamide, and nylon are preferable and filters using polytetrafluoroethylene (PTFT) are particularly preferable.

In addition, as the porous base materials, inorganic materials such as a silica base material, stainless, nickel, and carbon may be employed and composite materials obtained by combining the above-described resin materials and inorganic materials may be employed.

More specifically, for example, a non-woven fabric filter obtained by entangling resins or fibers of a metal or a mesh filter obtained by knitting resins or fibers of a metal can be used.

The polymer compound that has a constituent unit having a group represented by Formula (a0-1) will be described in a second embodiment in detail.

In the first embodiment, it is preferable that the group represented by the above-described Formula (a0-1) is a group represented by the following Formula (a0-1-1).

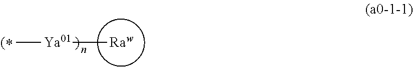

[In Formula (a0-1-1), Ya⁰¹ represents a divalent linking group. Ra^{W} represents a heteroatom-containing group, provided that Ra^{W} includes a nitrogen atom bonded to Ya⁰¹ and has two or more ether bonds or two or more groups represented by —NH— in the ring skeleton thereof; n represents a natural number; and the symbol “*” represents a valence bond with respect to the base material.]

In Formula (a0-1-1), description on the divalent linking group as Ya⁰¹ is the same as the description on the divalent linking group as Ya⁰¹ in Formula (a0-1) in the first embodiment of the present invention.

In Formula (a0-1-1), Ra^{W} represents a cyclic heteroatom-containing group which is bonded to Ya⁰¹ through a nitrogen atom and has two or more ether bonds or two or more groups represented by —NH— in a cyclic skeleton.

The cyclic polyether group represented by Formula (a0-r-1) or the polyamine group represented by Formula (a0-r-2) described in the first embodiment of the present invention may be exemplified as a group represented by Ra^{W}. Among these, a cyclic polyamine group is preferable.

The description on a base material modified with a group represented by Formula (a0-1-1) is the same as the description on the base material described in the first embodiment of the present invention.

In the first embodiment, it is preferable that a group represented by the above-described Formula (a0-1-1) is a group represented by the following Formula (a0-1-1-1).

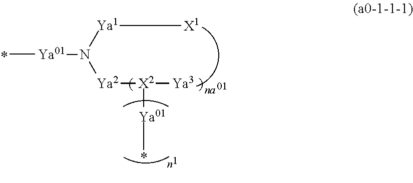

[In Formula (a0-1-1-1), Ya⁰¹ represents a divalent linking group. Ya¹ to Ya³ each independently represent a divalent aliphatic hydrocarbon group and Ya¹ to Ya³ may be the same as or different from each other. X¹ and X² are selected from an oxygen atom, a sulfur atom, or NR¹. The or each R¹ each independently represent a hydrogen atom or a methyl group. X¹ and X² may be the same as or different from each other. When plurality of X² are present, the plurality of X² may be the same as or different from each other. na₀₁ represents an integer of 1 to 7. n¹ represents 0 or a natural number. The symbol “*” represents a valence bond with respect to the base material.]

In Formula (a0-1-1-1), description on the divalent linking group as Ya⁰¹ is the same as the description on the divalent linking group as Ya⁰¹ in Formula (a0-1) according to the first embodiment of the present invention.

In Formula (a0-1-1-1), Ya¹ to Ya³ each independently represent a divalent aliphatic hydrocarbon group and Ya¹ to Ya³ may be the same as or different from each other.

As Ya¹ to Ya³, a linear aliphatic hydrocarbon group is preferable, a linear alkylene group is more preferable, a linear alkylene group having 1 to 5 carbon atoms is still more preferable, and a methylene group or an ethylene group is particularly preferable.

X¹ and X² are selected from an oxygen atom, a sulfur atom, or NR¹. R¹'s each independently represent a hydrogen atom or a methyl group. R¹ may be bonded to Ya⁰¹.

A plurality of X¹'s and X²'s may be the same as or different from each other.

The filtering material according to the first embodiment can be repeatedly used by capturing the metal components and releasing metal components using an acid.

### Second Embodiment

The second embodiment of a filtering material of the present invention will be described.

The second embodiment relates to a filtering material using a polymer compound that has a constituent unit represented by the following Formula (P-1). Hereinafter, the polymer compound that has a constituent unit represented by the following Formula (P-1) is also referred to as a “polymer compound (BM)”.

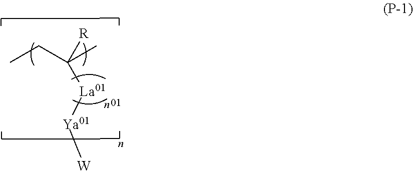

[In Formula (P-1), R represents a hydrogen atom, an alkyl group having 1 to 5 carbon atoms, or a halogenated alkyl group having 1 to 5 carbon atoms. La⁰¹ represents a divalent linking group containing an oxygen atom or a divalent aromatic cyclic group other than the divalent linking group containing an oxygen atom. Ya⁰¹ represents a divalent linking group. W represents a heteroatom-containing group, provided that the group represented by W includes a nitrogen atom bonded to Ya⁰¹ and two or more heteroatoms other than the nitrogen atom bonded to Ya⁰¹. n⁰¹ represents 0 or 1. n represents a natural number.]

In Formula (P-1), R represents a hydrogen atom, an alkyl group having 1 to 5 carbon atoms, or a halogenated alkyl group having 1 to 5 carbon atoms.

As the alkyl group having 1 to 5 carbon atoms as R, a linear or branched alkyl group having 1 to 5 carbon atoms is preferable and specific examples thereof include a methyl group, an ethyl group, a propyl group, an isopropyl group, an n-butyl group, an isobutyl group, a tert-butyl group, a pentyl group, an isopentyl group, or a neopentyl group. The halogenated alkyl group having 1 to 5 carbon atoms is a group in which some or all of hydrogen atoms of the alkyl group having 1 to 5 carbon atoms are substituted with halogen atoms. Examples of the halogen atom include a fluorine atom, a chlorine atom, a bromine atom, and an iodine atom. Among these, a fluorine atom is preferable.

As R, a hydrogen atom, an alkyl group having 1 to 5 carbon atoms, or a fluorinated alkyl group having 1 to 5 carbon atoms is preferable and a hydrogen atom or a methyl group is most preferable from the viewpoint of ease of industrial availability.

In Formula (P-1), La⁰¹ represents a divalent linking group having oxygen atoms or a divalent aromatic cyclic group other than the divalent linking group having oxygen atoms.

In Formula (P-1), examples of the divalent linking group having oxygen atoms as La⁰¹ include —O—, —C(═O)—O—, —C(═O)—, —O—C(═O)—O—, —C(═O)—NH—, and a group represented by Formula —Y³¹—O—Y³²—, —Y³¹—O—, —Y³¹—C(═O)—O—, —C(═O)—O—Y³¹—, —[Y³¹—C(═O)—O]_{m′}—Y³²—, or —Y³¹—O—C(═O)—Y³²— [in the formulae, Y³¹ and Y³² each independently represents a linear or branched divalent aliphatic hydrocarbon group which may have a substituent; O represents an oxygen atom; and m′ represents an integer of 0 to 3].

In Formula —Y³¹—O—Y³²—, —Y³¹—O—, —Y³¹—C(═O)—O—, —C(═O)—O—Y³¹—, —[Y³¹—C(═O)—O]_{m′}—Y³²—, or —Y³¹—O—C(═O)—Y³²—, as Y³¹, a linear aliphatic hydrocarbon group is preferable, a linear alkylene group is more preferable, a linear alkylene group having 1 to 5 carbon atoms is still more preferable, and a methylene group or an ethylene group is particularly preferable.

As Y³², a linear or branched aliphatic hydrocarbon group is preferable, and a methylene group, an ethylene group, or an alkylmethylene group is more preferable. As an alkyl group in the alkylmethylene group, a linear alkyl group having 1 to 5 carbon atoms is preferable, a linear alkyl group having 1 to 3 carbon atoms is more preferable, and a methyl group is most preferable.

In the group represented by Formula —[Y³¹—C(═O)—O]_{m′}—Y³²—, m′ represents an integer of 0 to 3, preferably an integer of 0 to 2, more preferably 0 or 1, and particularly preferably 1. That is, a group represented by Formula —Y³¹—C(═O)—O—Y³²— is particularly preferable as the group represented by Formula —[Y³¹—C(═O)—O]_{m′}—Y³²—. Among these, a group represented by Formula —(CH₂)ₐ—C(═O)—O—(CH₂)_{b′}— is preferable. In Formula, a′ represents an integer of 1 to 10, preferably an integer of 1 to 8, more preferably an integer of 1 to 5, still more preferably 1 or 2, and most preferably 1. b′ represents an integer of 1 to 10, preferably an integer of 1 to 8, more preferably an integer of 1 to 5, still more preferably 1 or 2, and most preferably 1.

In Formula (P-1), a divalent aromatic cyclic group in a case where La⁰¹ represents a divalent aromatic cyclic group other than the divalent linking group having oxygen atoms will be described.

Specific examples of the divalent aromatic cyclic group as La⁰¹ include groups formed by removing two hydrogen atoms from aromatic hydrocarbon rings such as benzene, biphenyl, fluorene, naphthalene, anthracene and phenanthrene.

Specific examples of the aromatic cyclic group include a group (arylene group) formed by removing two hydrogen atoms from the aromatic hydrocarbon ring; and a group in which one hydrogen atom of a group (aryl group) formed by removing one hydrogen atom from the aromatic hydrocarbon ring is substituted with an alkylene group (for example, a group formed by removing one more hydrogen atom from an aryl group in an arylalkyl group such as a benzyl group, a phenethyl group, a 1-naphthylmethyl group, a 2-naphthylmethyl group, a 1-naphthylethyl group, or a 2-naphthylethyl group). The number of carbon atoms of the alkylene group (alkyl chain in the arylalkyl group) is preferably in a range of 1 to 4, more preferably 1 or 2, and particularly preferably 1.

In Formula (P-1), it is preferable that La⁰¹ represents a divalent linking group having oxygen atoms.

In Formula (P-1), the descriptions on the divalent linking group as Ya⁰¹ and the heteroatom-containing group represented by W are the same as the descriptions on Ya⁰¹ and W in Formula (a0-1) described in the first embodiment of the present invention.

As the divalent linking group as Ya⁰¹ in Formula (P-1), among those described above, a linear or branched aliphatic hydrocarbon group having a hydroxyl group as a substituent is preferable.

As a constituent unit represented by Formula (P-1), a constituent unit represented by the following Formula (P-1-01) or (P-1-02) is preferable.

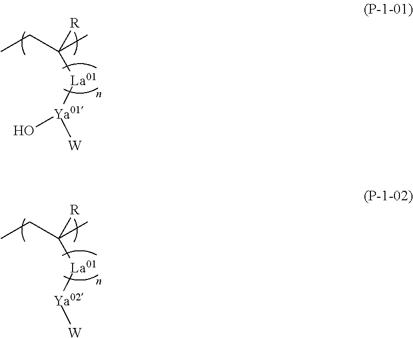

[In Formula (P-1-01) or (P-1-02), R represents a hydrogen atom, an alkyl group having 1 to 5 carbon atoms, or a halogenated alkyl group having 1 to 5 carbon atoms; La⁰¹ represents a divalent linking group containing an oxygen atom or a divalent aromatic cyclic group other than the divalent linking group containing an oxygen atom; Ya⁰¹′ represents a a linear or branched divalent aliphatic hydrocarbon group having a hydroxyl group as a substituent; Ya⁰²′ represents a linear or branched divalent aliphatic hydrocarbon group; and W represents a heteroatom-containing group, provided that the group represented by W is bonded to Ya⁰¹′ through a nitrogen atom and includes two or more heteroatoms other than the nitrogen atom bonded to Ya⁰¹′. n represents 0 or 1.]

In Formula (P-1-01) or (P-1-02), the descriptions on R, La⁰¹, and W are the same as the descriptions on R, La⁰¹, and W in the above-described Formula (P-1).

In Formula (P-1-01), Ya⁰¹′ represents a linear or branched divalent aliphatic hydrocarbon group having a hydroxyl group as a substituent. The number of carbon atoms of the linear or branched divalent aliphatic hydrocarbon group as Ya⁰¹′ is preferably in a range of 1 to 10, more preferably in a range of 1 to 6, still more preferably in a range of 1 to 4, and most preferably in a range of 1 to 3.

As the linear aliphatic hydrocarbon group, a linear alkylene group is preferable, and specific examples thereof include a methylene group [—CH₂—], an ethylene group a trimethylene group [—(CH₂)₃—], a tetramethylene group [—(CH₂)₄-] and a pentamethylene group [—(CH₂)₅—]. Among these, a methylene group [—CH₂—], an ethylene group [—(CH₂)₂—], or a trimethylene group [—(CH₂)₃-] is preferable.

As the branched aliphatic hydrocarbon group, a branched alkylene group is preferable, and specific examples thereof include alkylalkylene groups, for example, an alkylmethylene group such as —CH(CH₃)—, —CH(CH₂CH₃)—, —C(CH₃)₂—, —C(CH₃)(CH₂CH₃)—, —C(CH₃)(CH₂CH₂CH₃)—, or —C(CH₂CH₃)₂—; an alkylethylene group such as —CH(CH₃)CH₂—, —CH(CH₃)CH(CH₃)—, —C(CH₃)₂CH₂—, —CH(CH₂CH₃)CH₂—, or —C(CH₂CH₃)₂—CH₂—; an alkyltrimethylene group such as —CH(CH₃)CH₂CH₂— or —CH₂CH(CH₃)CH₂—; and an alkyltetramethylene group such as —CH(CH₃)CH₂CH₂CH₂— or —CH₂CH(CH₃)CH₂CH₂—. As an alkyl group in the alkylalkylene group, a linear alkyl group of 1 to 5 carbon atoms is preferable.

In Formula (P-1-02), Ya⁰²′ represents a linear or branched divalent aliphatic hydrocarbon group having a hydroxyl group as a substituent. Examples of the linear or branched divalent aliphatic hydrocarbon group as Ya⁰²′ are the same as the examples of the aliphatic hydrocarbon group described in Ya⁰¹′.

According to the second embodiment, in a case where a polymer compound having a constituent unit represented by Formula (P-1-01) is used, metal components are collected by an unshared electron pair of oxygen atoms or nitrogen atoms in the heteroatom-containing group represented by W. At this time, it is assumed that collecting performance of metal components is improved due to an influence of a hydroxyl group present in the vicinity of the heteroatom-containing group.

According to the second embodiment, since metal components are collected by an unshared electron pair of oxygen atoms or nitrogen atoms in the heteroatom-containing group represented by W even in a case where a polymer compound having a constituent unit represented by Formula (P-1-02) is used, the metal components can be efficiently removed.

According to the second embodiment, it is preferable that the constituent unit represented by Formula (P-1) is a constituent unit represented by the following Formula (P-1-1-1).

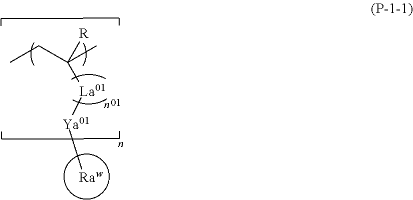

[In Formula (P-1-1), R represents a hydrogen atom, an alkyl group having 1 to 5 carbon atoms, or a halogenated alkyl group having 1 to 5 carbon atoms; La⁰¹ represents a divalent linking group containing an oxygen atom or a divalent aromatic cyclic group other than the divalent linking group containing an oxygen atom; Ya⁰¹ represents a divalent linking group; and Ra^{W} represents a cyclic heteroatom-containing group, provided that Ra^{W} includes a nitrogen atom bonded to Ya⁰¹ and has two or more ether bonds or two or more groups represented by —NH— in the ring skeleton thereof; n represents a natural number; and n⁰¹ represents 0 or 1.]

In Formula (P-1-1), the descriptions on R, La⁰¹, n, and n⁰¹ are the same as the descriptions on R, La⁰¹, n, and n⁰¹ in the above-described Formula (P-1).

In Formula (P-1-1), the description on Ra^{W} is the same as the description on Ra^{W} in the above-described Formula (a0-1-1).

According to the second embodiment, it is preferable that the constituent unit represented by Formula (P-1-1) is a constituent unit represented by the following Formula (P-1-1-1).

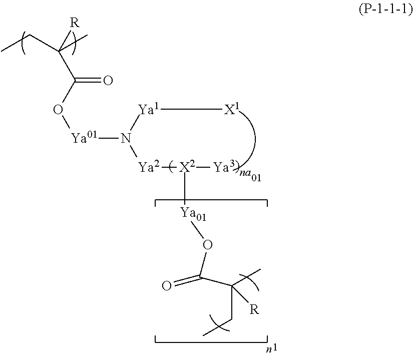

[In Formula (P-1-1-1), R represents a hydrogen atom, an alkyl group having 1 to 5 carbon atoms, or a halogenated alkyl group having 1 to 5 carbon atoms; Ya⁰¹ represents a divalent linking group; Ya¹ to Ya³ each independently represent a divalent aliphatic hydrocarbon group, and Ya¹ to Ya³ may be the same as or different from each other. X¹ and X² are selected from an oxygen atom, a sulfur atom, or NR¹. The or each R¹ independently represent a hydrogen atom or a methyl group. X¹ and X² may be the same as or different from each other. When plurality of X² are present, the plurality of X² may be the same as or different from each other. na₀₁ represents an integer of 1 to 7. n¹ represents 0 or a natural number.]

In Formula (P-1-1-1), the descriptions on Ya⁰¹, Ya¹ to Ya³, X, and na₀₁ are the same as the descriptions on Ya⁰¹, Ya¹ to Ya³, X¹, X², and na₀₁ in Formula (a0-1-2) according to the first embodiment of the present invention.

In Formula (P-1-1-1), the description on R is the same as the description on R in Formula (P-1).

Hereinafter, specific examples of the constituent unit represented by Formula (P-1) will be described.

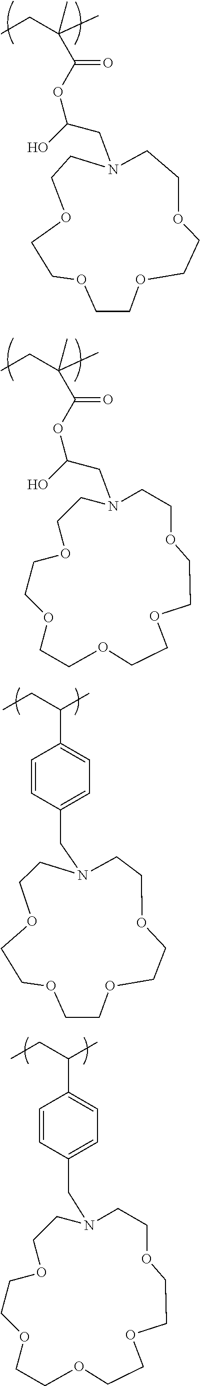

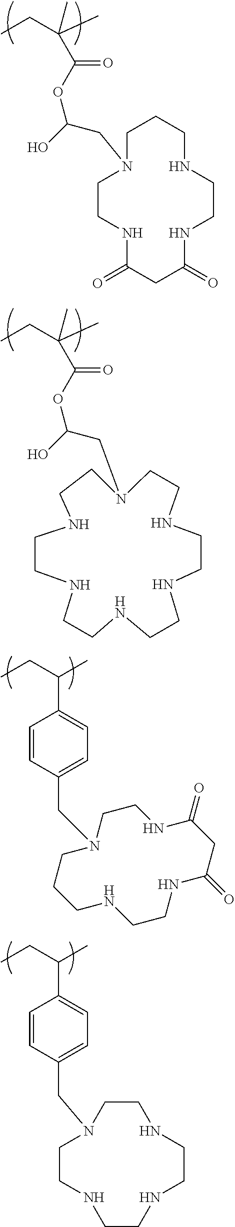

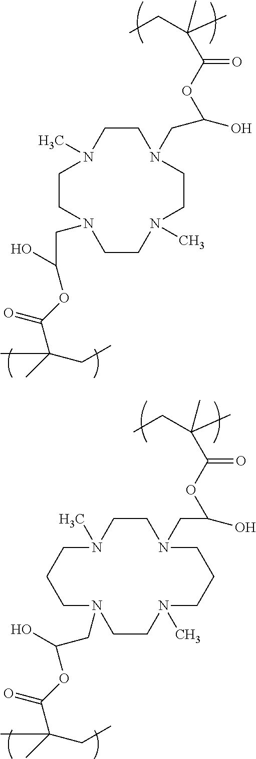

The proportion of the constituent unit represented by Formula (P-1) in the polymer compound (BM) is preferably in a range of 1% to 100% by mole, more preferably in a range of 20% to 100% by mole, and particularly preferably in a range of 30% to 100% by mole with respect to all constituent units constituting the polymer compound (BM).

The constituent unit represented by Formula (P-1) may be used alone or in combination of two or more kinds thereof.

Moreover, the polymer compound (BM) may contain a constituent unit other than the constituent unit represented by Formula (a0-1) within the range not damaging the effects of the present invention.

Examples of other constituent units include a constituent unit derived from styrene, ethoxylated isocyanuric acid triacrylate, ε-caprolactone-modified tris-(2-acryloxyethyl) isocyanurate, pentaerythritol triacrylate (triester), dimethylol propane tetraacrylate, acrylate such as acrylic acid, or an acrylamide monomer; a constituent unit derived from 2-acrylamido-2-methyl-1-propanesulfonic acid; a constituent unit derived from sulfopropyl acrylate or N,N-dimethyl acrylamide; and a constituent unit derived from a methacrylamide monomer such as methacrylate or methacrylic acid.

The polymer compound (BM) can be obtained by polymerization, for example, known radical polymerization or the like, using a radical polymerization initiator such as azobisisobutyronitrile (AIBN) or dimethyl azobis(isobutyrate).

Further, a crosslinking agent may be used at the time of polymerization of the polymer compound (BM). As the crosslinking agent, compounds including an ethylenically unsaturated group can be used and these compounds can be used alone or in combination thereof. Preferred examples of the compounds include an ethylenically unsaturated group include polyacrylates of polyols such as ethylene glycol diacrylate, trimethylol propane triacrylate, ditrimethylol propane tetraacrylate, pentaerythritol triacrylate, pentaerythritol tetraacrylate, dipentaerythritol pentaacrylate, and dipentaerythritol hexaacrylate; epoxyacrylates such as diacrylate of bisphenol A diglycidyl ether and diacrylate of hexanediol diglycidyl ether; and urethane acrylate obtained by a reaction of hydroxyl group-containing acrylate such as polyisocyanate or hydroxyethyl acrylate. From the viewpoint of chemical resistance to an organic solvent, an aromatic vinyl compound such as divinyl benzene, trivinyl benzene, divinyl toluene, or divinyl naphthalene are preferable and divinyl benzene is more preferable.

The filtering material according to the second embodiment can be repeatedly used by capturing the metal components and releasing metal components using an acid.

### Production Example 1

An example of a method of producing the filtering material according to the second embodiment will be described below. Hereinafter, a production example of a polymer compound that has a constituent unit represented by Formula (P-1-01) will be described.

As shown from the following reaction formula, a polymer compound having a constituent unit represented by Formula (P-1-01) can be produced by modifying a polymer compound having a constituent unit represented by Formula (PS-1) with a compound W′.

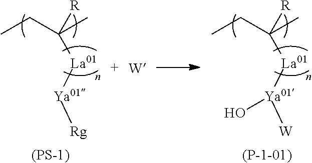

[In the above-described formulae, R represents a hydrogen atom, an alkyl group having 1 to 5 carbon atoms, or a halogenated alkyl group having 1 to 5 carbon atoms; La⁰¹ represents a divalent linking group having oxygen atoms or a divalent aromatic cyclic group; Ya⁰¹″ represents a single bond or a divalent linking group; Rg represents a glycidyl group-containing group; and W′ represents a nitrogen atom or a compound having two or more heteroatoms other than the nitrogen atom. Ya⁰¹′ represents a linear or branched divalent aliphatic hydrocarbon group, and W represents a heteroatom-containing group. Here, the group represented by W is bonded to Ya⁰¹′ through a nitrogen atom and includes two or more heteroatoms other than the nitrogen atom bonded to Ya⁰¹′. n represents 0 or 1.]

In the above-described Formula (PS-1) or (P-1-01), the descriptions on R, La⁰¹, Ya⁰¹′, and W are the same as the descriptions on R, La⁰¹, Ya⁰¹, Ya⁰¹′, and W in the above-described Formula (P-1) or (P-1-01). Moreover, Ya⁰¹″ represents a single bond or a divalent linking group, and the description on the divalent linking group as Ya⁰¹″ is the same as the description on the divalent linking group as Ya⁰¹.

In the above-described Formula (PS-1), Rg represents a glycidyl group-containing group.

W′ represents a nitrogen atom or a compound having two or more heteroatoms other than the nitrogen atom. Examples of the compound represented by W′ include cyclic polyether, cyclic polyamine, or chain or cyclic polyethyleneimine, which has at least one nitrogen atom.

Examples of the constituent unit represented by the above-described Formula (PS-1) include constituent units derived from butadiene epoxide, 3,4-epoxy cyclohexyl methyl methacrylate, 3,4-epoxy cyclohexyl methyl acrylate, 1,2-epoxy-4-vinyl cyclohexane, and the like.

The conditions for modifying the polymer compound which has a constituent unit represented by Formula (PS-1) with the compound W′ are not particularly limited, and a known modification method of carrying out modification in a solvent such as propylene glycol monoether acetate can be employed.

The reaction temperature may be suitably adjusted typically in a range of 20° C. to 150° C. and preferably in a range of 40° C. to 120° C.

The reaction time may be suitably adjusted in a range of 60 minutes to 800 minutes.

### Another Production Example

In addition to the production example described above, an example of a method of producing the filtering material according to the second embodiment will be described below. Hereinafter, a production example of a polymer compound that has a constituent unit represented by Formula (P-1-02) will be described.

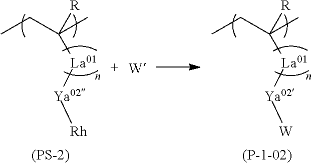

[In the above-described formulae, R represents a hydrogen atom, an alkyl group having 1 to 5 carbon atoms, or a halogenated alkyl group having 1 to 5 carbon atoms; La⁰¹ represents a divalent linking group having oxygen atoms or a divalent aromatic cyclic group; Ya⁰²″ represents a single bond or a divalent linking group; Rh represents a halogen atom; and W′ represents a nitrogen atom or a compound having two or more heteroatoms other than the nitrogen atom. Ya⁰²′ represents a linear or branched divalent aliphatic hydrocarbon group, and W represents a heteroatom-containing group. Here, the group represented by W is bonded to Ya⁰¹′ through a nitrogen atom and includes two or more heteroatoms other than the nitrogen atom bonded to Ya⁰¹′. n represents 0 or 1].

In the above-described Formula (PS-2) or (P-1-02), the descriptions on R, La⁰¹, Ya⁰²′, and W are the same as the descriptions on R, La⁰¹, Ya⁰¹′, and W in the above-described Formula (P-1) or (P-1-01). Moreover, Ya⁰¹″ represents a single bond or a divalent linking group, and the description on the divalent linking group as Ya⁰¹″ is the same as the description on the divalent linking group as Ya⁰¹.

In the above-described Formula (PS-2), Rh represents a halogen atom. Preferred examples of the halogen atom as Rh include a chlorine atom and a bromine atom.

W′ represents a nitrogen atom or a compound having two or more heteroatoms other than the nitrogen atom. Examples of the compound represented by W′ include cyclic polyether, cyclic polyamine, or chain or cyclic polyethyleneimine, which has at least one nitrogen atom.

Examples of the constituent unit represented by the above-described Formula (PS-2) include constituent units derived from chloromethylstyrene, bromomethylstyrene, acryl chloride, and the like.

The conditions for modifying the polymer compound with the compound W′ are not particularly limited, and a known modification method of carrying out modification in a solvent such as propylene glycol monoether acetate can be employed.

The reaction temperature may be suitably adjusted typically in a range of 20° C. to 150° C. and preferably in a range of 40° C. to 120° C.

The reaction time may be suitably adjusted in a range of 60 minutes to 800 minutes.

In addition to the above-described production examples, the polymer compound (BM) may be produced by modifying a polymer compound having a constituent unit derived from acrylic acid or methacrylic acid with W′.

The desired shape of the filtering material according to the second embodiment of the present invention can be suitably selected. The shape thereof may be a flat shape, a roll shape, a cone shape, a pleated shape, a spiral shape, a layered type, or a combination of these. Among these, a flat shape or a roll shape is preferable.

Furthermore, the filter having a flat shape may be used, for example, as a cut disk having a diameter of 20 mm to 300 mm.

Moreover, the filtering material of the present embodiment may be a cartridge type. As the cartridge type filter, for example, a cartridge device which is formed as one or more layers, and has pleats or is wound up spirally is preferable. Further, a cartridge device having a flat shape and sheet shape is more preferable.

Further, the filtering material according to the second embodiment can be produced by modifying a known porous base material with the polymer compound (BM) with a crosslinking agent or simply coating a known porous base material with the polymer compound (BM).

Filtration Filter

The second embodiment of the present invention relates to a filtration filter using the above-described filtering material. As the filtration filter of the present invention, a filter formed by filling a cylindrical container having a liquid inlet and a liquid outlet with the filtering material may be exemplified.

The shape of the filter and the amount of the filtering material used for filling can be suitably adjusted and may be suitably selected according to a resist composition to be filtered, an organic solvent, and the like.

The shape of the filtration filter of the present invention may be a flat shape, a roll shape, a cone shape, a pleated shape, a spiral shape, a layered type, or a combination of these. Among these, a flat shape or a roll shape is preferable.

Moreover, the filtration filter of the present embodiment may be a cartridge type. As the cartridge type filter, for example, a cartridge device which is formed as one or more layers, and has pleats or is wound up spirally is preferable. Further, a cartridge device having a flat shape and sheet shape is more preferable.

Filtration Method

A third embodiment of the present invention relates to a filtration method including passing a liquid chemical for lithography through the filtration filter of the second embodiment of the present invention, and removing impurities in the liquid chemical for lithography.

The filtration method of the present invention can be performed using (1) a method (column method) of filling a column with the filtering material and passing a liquid chemical for lithography through the column for purification and (2) a method (batch method) of putting the filtering material in a liquid chemical for lithography and mixing and stirring the solution for a predetermined time for removal. In a case of the batch method, it is necessary to separate the filtering material from the liquid chemical for lithography after the solution is stirred for a predetermined time. The separation method is typically carried out through filtration using a filter or carried out using a centrifugation technique.

The flow rate of the liquid chemical for lithography passing through the filtering medium is unlikely to affect the efficiency of metal separation, and is typically and suitably set in a range of 0.0001 to 1000 kg/(m²·min). When the temperature of the liquid chemical passing through the filter filled with the filtering material is too high, there is a concern that elution or deterioration of the filtering medium or degradation of a solvent may occur. Therefore, the appropriate range of the temperature is 0° C. to 50° C.

The filtration method of the present invention can be applied to a liquid chemical for lithography used in semiconductor photolithography.

The liquid chemical for photolithography which is to be filtered is not particularly limited, and examples thereof include various liquid chemicals used to manufacture semiconductor elements or liquid crystal display elements.

The liquid chemical for photolithography contains a liquid chemical used to form a resist pattern, and examples thereof include an alkaline solution, a resist composition, an insulating film forming resin composition, an antireflection film forming resin composition, and a block copolymer composition used for a directed self assembly (DSA) technique.

The descriptions on an alkaline solution, a resist composition, an insulating film forming resin composition, an antireflection film forming composition, and a block copolymer composition applied to the directed self assembly (DSA) technique, to which the filtration method of the present invention is applied, are the same as those described in the filtering material according to the first embodiment of the present invention.

In the filtration method of the present invention, metal components can be preferably removed.

According to the filtration method according to the present invention, metal components such as lithium, sodium, magnesium, potassium, chromium, manganese, iron, cobalt, nickel, copper, zinc, strontium, molybdenum, silver, cadmium, tin, antimony, barium, lead, and the like can be removed. Among these, metal ions having a high ionization tendency, for example, an alkali metal ion such as a potassium ion or a sodium ion and an alkaline-earth metal ion such as calcium; and heavy metal ions such as an iron ion and a nickel ion can be removed.

According to the filtration method of the present invention, even in the case where two or more kinds of these metal components are present in a mixture, the metal components can be removed.

Among the above-described metal components, metal components having a high ionization tendency can be effectively removed.

### EXAMPLES

Hereinafter, the present invention will be described in more detail with reference to examples, but the present invention is not limited to the following examples.

### Example 1

Synthesis was carried out with reference to literatures (H. Egawa, et al., Anal. Sci, 1992, 8, 195 to 200 and Japanese Examined Patent Application, Second Publication No. H5-21123).

1 part by mass of poly(glycidyl methacrylate) synthesized in advance, 2 parts by mass of 1-aza-15-crown 5-ether, and 4 parts by mass of propylene glycol monomethylether acetate were added to a vial, stirred, and then allowed to stand in an oven at 100° C. for 24 hours. The vial was taken out from the oven, and the obtained polymer was sufficiently washed with methanol and dried in a vacuum for 24 hours, thereby obtaining a cyclic polyether group-modified polymer described below. The reaction formula is shown below.

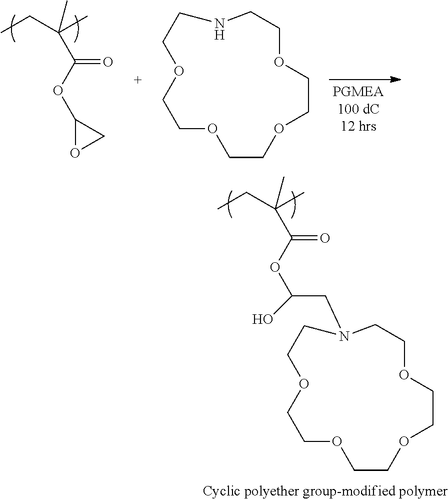

When FT-IR of each polymer was measured before and after the modification reaction using 1-aza-15-crown 5-ether, after the reaction, a peak derived from an ether group resulting from ring opening of an epoxy ring at a glycidyl site belonging to a region of 1000 to 1200 cm⁻¹ and a peak derived from a CN group bond resulting from a reaction of a glycidyl site belonging to a region of 1600 to 1700 cm⁻¹ and an amino group of 1-aza-15-crown 5-ether were observed. In this manner, it was confirmed that the cyclic polyether group-modified polymer was obtained. The cyclic polyether group-modified polymer obtained in Example 1 was used as a filtering material.

### Example 2

Synthesis was carried out with reference to literatures (H. Egawa, et al., Anal. Sci, 1992, 8, 195 to 200 and Japanese Examined Patent Application, Second Publication No. H5-21123).

1 part by mass of poly(glycidyl methacrylate) synthesized in advance, 2 parts by mass of dimethyl tetraazacyclotetradecane, and 4 parts by mass of propylene glycol monomethylether acetate were added to a vial, stirred, and then allowed to stand in an oven at 100° C. for 24 hours. The vial was taken out from the oven, and the obtained polymer was sufficiently washed with methanol and dried in a vacuum for 24 hours, thereby obtaining a cyclic polyamine group-modified polymer described below. The reaction formula is shown below.

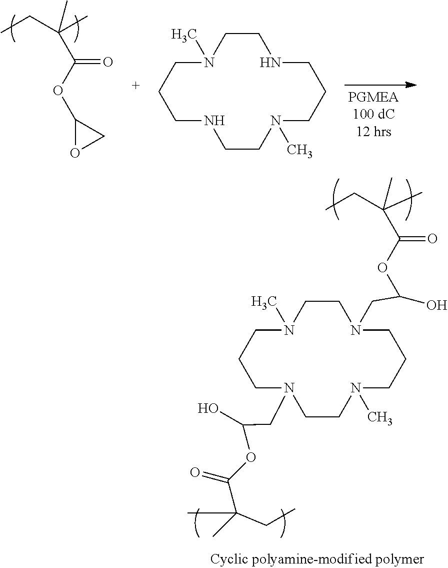

When FT-IR of each polymer was measured before and after the modification reaction using dimethyl tetraazacyclotetradecane, after the reaction, a peak derived from an ether group resulting from ring opening of an epoxy ring at a glycidyl site belonging to a region of 1000 to 1200 cm⁻¹ and a peak derived from a CN group bond resulting from a reaction of a glycidyl site belonging to a region of 1600 to 1700 cm⁻¹ and an amino group of dimethyl tetraazacyclotetradecane were observed. In this manner, it was confirmed that the cyclic polyamine group-modified polymer was obtained. The cyclic polyamine group-modified polymer 1 obtained in Example 2 was used as a filtering material.

### Example 3

1 part by mass of a poly(glycidyl methacrylate)-dipentaerythritol hexaacrylate spherical cross-linked body which was synthesized by carrying out suspension polymerization in advance and had a diameter of 50 to 200 μm, 2 parts by mass of 1-aza-15-crown 5-ether, and 4 parts by mass of propylene glycol monoethylether acetate were added to a 50 mL eggplant flask, stirred, and then allowed to stand in an oven at 100° C. for 24 hours. The flask was taken out from the oven, and the obtained polymer was sufficiently washed with methanol and dried in a vacuum for 24 hours, thereby obtaining a cyclic polyamine group-modified polymer 2 through the same reaction as in Example 2 described above.

### Example 4

1 part by mass of a chloromethylstyrene-divinyl benzene cross-linked body which was synthesized in advance and had a diameter of 50 to 200 μm, 2 parts by mass of 1-aza-15-crown 5-ether, and 4 parts by mass of propylene glycol monomethylether acetate were added to a vial, stirred, and then allowed to stand in an oven at 60° C. for 24 hours. The vial was taken out from the oven, and the obtained polymer was sufficiently washed with methanol and dried in a vacuum for 24 hours, thereby obtaining a cyclic polyamine group-modified polymer 3 through the same reaction as in Example 2 described above.

Metal Ion Collecting Test

A metal ion collecting test was performed by using the cyclic polyether group-modified polymer obtained in Example 1 and the cyclic polyamine group-modified polymer 1 obtained in Example 2.

Pre-Treatment

In order to remove metal ions which might be incorporated in a polymer before the metal ion collecting test was performed, each polymer was washed with 0.01 mol/L of a hydrochloric acid aqueous solution, further washed with ultra-pure water and then ethanol, and then dried.

0.3 g of the cyclic polyether group-modified polymer or 0.3 g of the cyclic polyamine-group modified polymer was added to 5 mL of each metal solution listed in the following Table 1 and the solution was stirred. The color of the metal solution was visually confirmed before and after the stirring. The results thereof are listed in Table 1. The solution was stirred for a few minutes in Test Example 1 and the solution was stirred for 24 hours in Test Example 2. Hereinafter, the “TMAH” indicates 2.38% by mass of tetramethyl ammonium hydroxide.

TABLE 1

| | Test Example 1 | | Test Example 2 | |
|---|---|---|---|---|
| | Cyclic polyether | | Cyclic polyamine | |
| | group-modified polymer | | group-modified polymer 1 | |
| | Metal solution | | | |
| | 0.05 mol/L of | 0.05 mol/L of | | |
| | potassium | potassium | 0.05 mol/L of | 0.05 mol/L of |
| | permanganate | permanganate | iron chloride | iron chloride |
| Metal Solvent | TMAH | Water | TMAH | Water |
| Before collection of metal | Violet | Violet | Yellow | Yellow |
| After collection of metal | Green | Colorless | Colorless | Colorless |

### Regarding Test Example 1

When the cyclic polyether group-modified polymer was added to the potassium permanganate aqueous solution, the violet color instantaneously disappeared and became colorless. From this result, it was confirmed that potassium ions were collected by polyether in a case where water was used as a solvent.

Meanwhile, when 2.38% TMAH was used as a solvent, the color of the solution was changed from violet into green.

It was considered that potassium ions were collected by polyether even in the case where 2.38% TMAH was used as a solvent. The reaction mechanism related to coloration of the solution is assumed as follows.

Reaction Mechanism for Change in Coloration of Solution

When the cyclic polyether group-modified polymer are added to the potassium permanganate aqueous solution, potassium ions are captured by polyether so that anions (MnO₄⁻) exist outside of the ring thereof as shown in the following Scheme. 1.

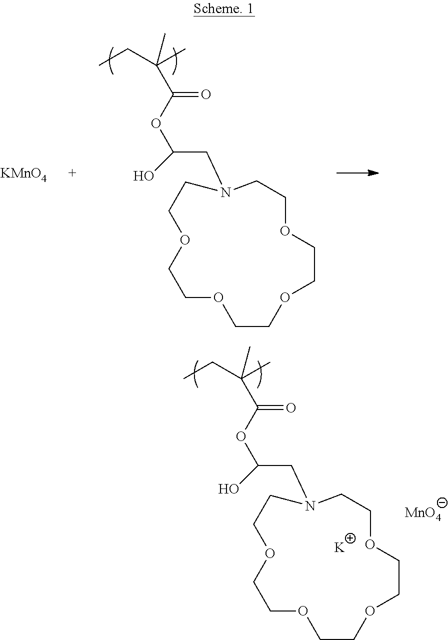

The anions (MnO₄⁻) generated in the above-described manner have an extremely high activity. It was considered that the color of the solution was changed from violet to green since MnO₄⁻ existing in a 2.38% TMAH solution was reduced in an alkali aqueous solution under the conditions in which an excessive amount of base was present and MnO₄²⁻ was generated (see the following Reaction Formula (1)).

MnO₄⁻→MnO₄²⁻ (1)

In Test Example 1, when water was used as a solvent, it was considered that chelate was formed by permanganic acid ions and polyether so that permanganic acid ions were collected and then the color of the aqueous solution became colorless because a base was not present in the aqueous solution.

As shown in Test Example 1 described above, even in a case where 2.38% TMAH was used as a solvent, it was confirmed that potassium ions, which are alkali metal ions, were collected similarly to the case where water was used as a solvent.

### Regarding Test Example 2

When a cyclic polyamine group-modified polymer was added to each iron chloride solution and the solution was stirred for 24 hours and then filtered, the color of the solution was changed from yellow to colorless in both cases of using 2.38% TMAH and water as a solvent. From this result, it was confirmed that chelate was formed by azacrown of the cyclic polyamine group-modified polymer and FeCl₃ so that iron ions were collected.

As shown in Test Example 2 described above, iron ions, which are heavy metal ions, present in a TMAH aqueous solution which is an alkaline solution was able to be removed using the filtering material of the present invention.

While preferred embodiments of the invention have been described and illustrated above, it should be understood that these are exemplary of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims.

What is claimed is:

1. A filtering material which is used to filter a liquid chemical for lithography, comprising:
a base material having a group represented by the following Formula (a0-1):
(*-Ya⁰¹ₙW (a0-1)
wherein Ya⁰¹ represents a divalent linking group; W represents a heteroatom-containing group, provided that the group represented by W includes a nitrogen atom bonded to Ya⁰¹ and two or more heteroatoms other than the nitrogen atom bonded to Ya⁰¹; n represents a natural number; and * represents a valence bond with respect to the base material.

2. The filtering material according to claim 1, wherein the liquid chemical for lithography is an alkaline solution.

3. The filtering material according to claim 1, wherein W represents a heteroatom-containing group having two or more ether bonds or two or more groups represented by —NH—.

4. The filtering material according to claim 1, wherein the group represented by Formula (a0-1) is a group represented by the following Formula (a0-1-1): 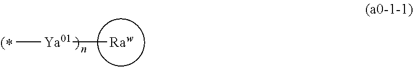
wherein Ya⁰¹ represents a divalent linking group; Ra^{W} represents a cyclic heteroatom-containing group, provided that Ra^{W} represents a group which has a nitrogen atom bonded to Ya⁰¹ and has two or more ether bonds or two or more groups represented by —NH— in a cyclic skeleton; n represents a natural number; and * represents a valence bond with respect to the base material.

5. The filtering material according to claim 4, wherein the group represented by Formula (a0-1-1) is a group represented by the following Formula (a0-1-1-1), 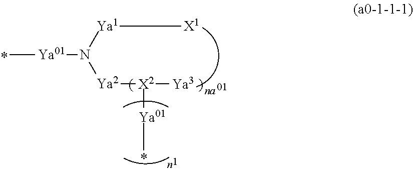
wherein Ya⁰¹ represents a divalent linking group; Ya¹ to Ya³ each independently represent a divalent aliphatic hydrocarbon group and Ya¹ to Ya³ may be the same as or different from each other; X¹ and X² are selected from an oxygen atom, a sulfur atom, or NR¹; the or each R¹ independently represents a hydrogen atom or a methyl group; X¹ and X² may be the same as or different from each other; when plurality of X² are present, the plurality of X² may be the same as or different from each other; na₀₁ represents an integer of 1 to 7; n¹ represents 0 or a natural number; and * represents a valence bond with respect to the base material.

6. A filtering material which is used to filter a liquid chemical for lithography, comprising:
a polymer compound having a constituent unit represented by the following Formula (P-1): 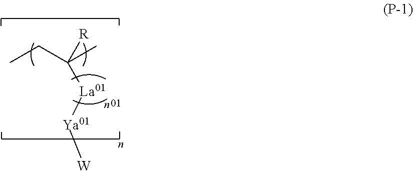
wherein R represents a hydrogen atom, an alkyl group having 1 to 5 carbon atoms, or a halogenated alkyl group having 1 to 5 carbon atoms; La⁰¹ represents a divalent linking group having oxygen atoms or an aromatic cyclic group other than the divalent linking group having oxygen atoms; Ya⁰¹ represents a divalent linking group; W represents a heteroatom-containing group, here, the group represented by W includes a nitrogen atom bonded to Ya⁰¹ and two or more heteroatoms other than the nitrogen atom bonded to Ya⁰¹; n⁰¹ represents 0 or 1; and n represents a natural number.

7. The filtering material according to claim 6, wherein the liquid chemical for lithography is an alkaline solution.

8. The filtering material according to claim 6, wherein the constituent unit represented by Formula (P-1) is a constituent unit represented by the following Formula (P-1-1): 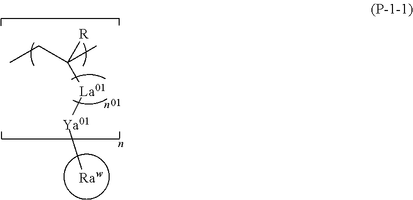
wherein R represents a hydrogen atom, an alkyl group having 1 to 5 carbon atoms, or a halogenated alkyl group having 1 to 5 carbon atoms; La⁰¹ represents a divalent linking group having oxygen atoms or a divalent aromatic cyclic group other than the divalent linking group having oxygen atoms; Ya⁰¹ represents a divalent linking group; Ra^{W} represents a cyclic heteroatom-containing group, provided that Ra^{W} includes a nitrogen atom bonded to Ya⁰¹ and has two or more ether bonds or two or more groups represented by —NH— in the ring skeleton thereof; n represents a natural number; and n⁰¹ represents 0 or 1.

9. The filtering material according to claim 8, wherein the constituent unit represented by Formula (P-1-1) is a constituent unit represented by the following Formula (P-1-1-1): 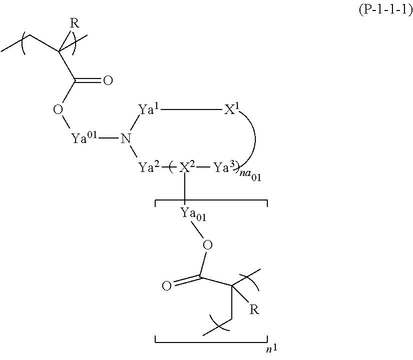
wherein R represents a hydrogen atom, an alkyl group having 1 to 5 carbon atoms, or a halogenated alkyl group having 1 to 5 carbon atoms; Ya⁰¹ represents a divalent linking group; Ya¹ to Ya³ each independently represent a divalent aliphatic hydrocarbon group and Ya¹ to Ya³ may be the same as or different from each other; X¹ and X² are selected from an oxygen atom, a sulfur atom, or NR¹; the or each R¹ independently represent a hydrogen atom or a methyl group; X¹ and X² may be the same as or different from each other; when plurality of X² are present, the plurality of X² may be the same as or different from each other; na₀₁ represents an integer of 1 to 7; and n¹ represents 0 or a natural number.

10. The filtering material according to claim 2, wherein the alkaline solution is an alkali metal aqueous solution or an alkali developer.

11. A filtration filter comprising the filtering material according to claim 1.

12. A filtration method comprising:
passing a liquid chemical for lithography through the filtration filter according to claim 11; and
removing impurities in the liquid chemical for lithography.

13. The filtration method according to claim 12, wherein the liquid chemical for lithography is an alkaline solution.

14. The filtration method according to claim 12, wherein the impurities are metal components.

15. The filtration method according to claim 13, wherein the alkaline solution is an alkali metal aqueous solution or an alkali developer.
